(19) United States
(12) Patent Application Publication
(10) Pub. No.: US 2006/0292775 A1
(43) Pub. Date: Dec. 28, 2006

(54) Method of manufacturing DRAM capable of avoiding bit line leakage

(75) Inventors: Ping Hsu, Taipei (TW); Yinan Chen, Taipei (TW); Wen-Hsiung Chang, Taipei (TW)

Correspondence Address: BIRCH STEWART KOLASCH & BIRCH, PO BOX 747, FALLS CHURCH, VA, 22040-0747, US

(73) Assignee: NANYA TECHNOLOGY CORPORATION

(21) Appl. No.: 11/167,168

(22) Filed: Jun. 28, 2005

(51) Int. Cl. H01L 21/8242; H01L 21/8234; H01L 21/336

(52) U.S. Cl. 438/197

(57) ABSTRACT

A method to make DRAM capable of avoiding bit line leakage is provided. The method comprise the steps of forming transistors on substrate, forming an insulating layer to cover the substrate and the transistors, forming a poly-silicon layer over the insulating layer, forming contact holes in the poly-silicon layer and the insulating layer, the contact holes touching the substrate, filling the contact holes with a conducting layer, and etching the surface of the conducting layer with O₂/O₃ plasma or an etchant of H₂SO₄, H₂O₂ and HF.

### FIELD OF INVENTION

The present invention generally relates to a method of manufacturing a DRAM, and more particularly, to a method of manufacturing a DRAM capable of avoiding bit line leakage.

### BACKGROUND OF THE INVENTION

There are a lot of contact holes formed during the formation of DRAM, including bit line contact holes, substrate contact holes and gate contact holes. Through these contact holes, the conductive wires can be formed to connect to the drain, substrate and gate. For example, the fabrication method of the above-mentioned DRAM structure is disclosed in the U.S. Pat. No. 6,780,739 and Taiwan patent application No. 92128778.

In 0.11-um CMOS process, the width of a bit line contact hole is about 140 nm to 160 nm, and the pitch of the bit line is about 220 nm. Therefore, with the minification of the device, the distance between each two bit lines, between each two bit line contact holes, or between a bit line and a bit line contact hole is becoming more and more short, which causes the electric short easily and consequently result in leakage. For example, the scratches caused by chemical mechanical polishing, the stringers in the poly-silicon layer, or the offset of the bit line contact hole might produce leakage. The type of leakage varies with the location of the stringer, including bit line to bit line leakage, bit line contact hole to bit line contact hole leakage, and bit line to bit line contact hole leakage.

Accordingly, it is advantageous to have a method of fabricating DRAM to avoid leakage caused by the above-mentioned scratches and stringers.

### SUMMARY OF THE INVENTION

To solve the above-mentioned problems, the present invention provides a method to make DRAM capable of avoiding bit line leakage.

According to an aspect of the present invention, a method of forming a DRAM capable of avoiding bit line leakage comprises the following steps: forming a transistor with a gate, a drain and a source on a substrate; forming an insulating layer to cover the substrate and the transistor; forming a poly-silicon layer over the insulating layer; forming a contact hole to touch the substrate in the poly-silicon layer and the insulating layer; filling the contact hole with a conducting layer; and microetching a surface of the conducting layer.

The method of forming the insulating layer further comprises the following steps: forming a first insulating layer to cover the substrate and the transistor; planarizing the first insulating layer to expose an upper surface of the gate of the transistor; and forming a second insulating layer to cover the insulating layer and the upper surface of the gate. In an embodiment of the present invention, the first insulating layer can be, but not limited to, BPSG (boron-phospho-silicate glass), and the second insulating layer can be, but not limited to, Tetraethoxysilane (TEOS).

According to another aspect of the present invention, the method of microetching the surface of the conducting layer is etching with O₂/O₃ plasma.

According to a further aspect of the present invention, the method of microetching the surface of the conducting layer is etching with an etchant comprised of H₂SO₄, H₂O₂ and HF.

The method of forming a DRAM capable of avoiding bit line leakage further comprises a step of etching the poly-silicon layer with Cl-based or Br-based plasma after microetching the surface of the conducting layer.

### BRIEF DESCRIPTION OF THE PICTURES

The foregoing aspects and many of the attendant advantages of this invention will become more readily appreciated as the same becomes better understood by reference to the following detailed description, when taken in conjunction with the accompanying pictures, wherein:

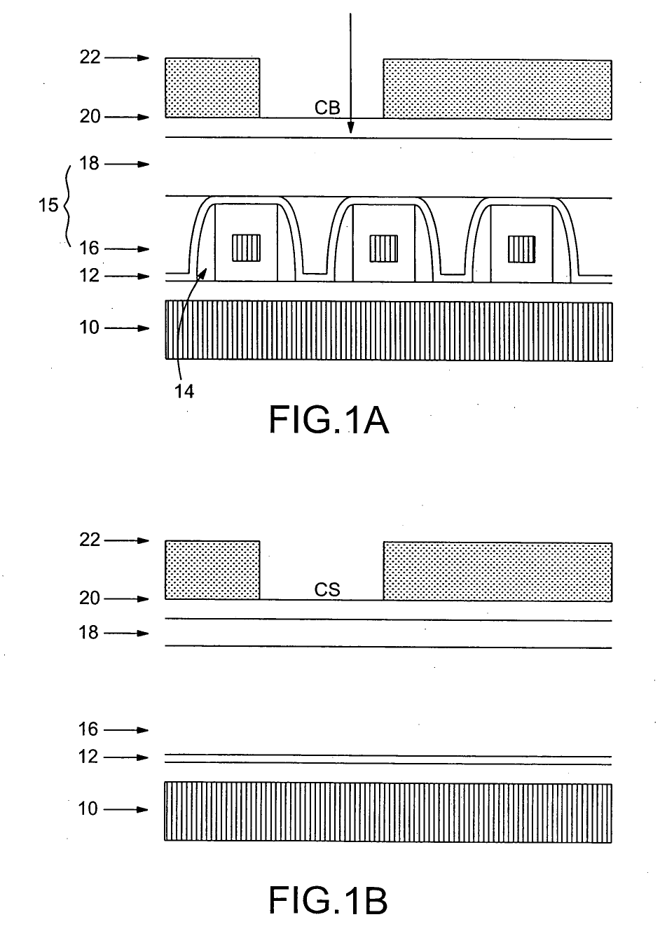

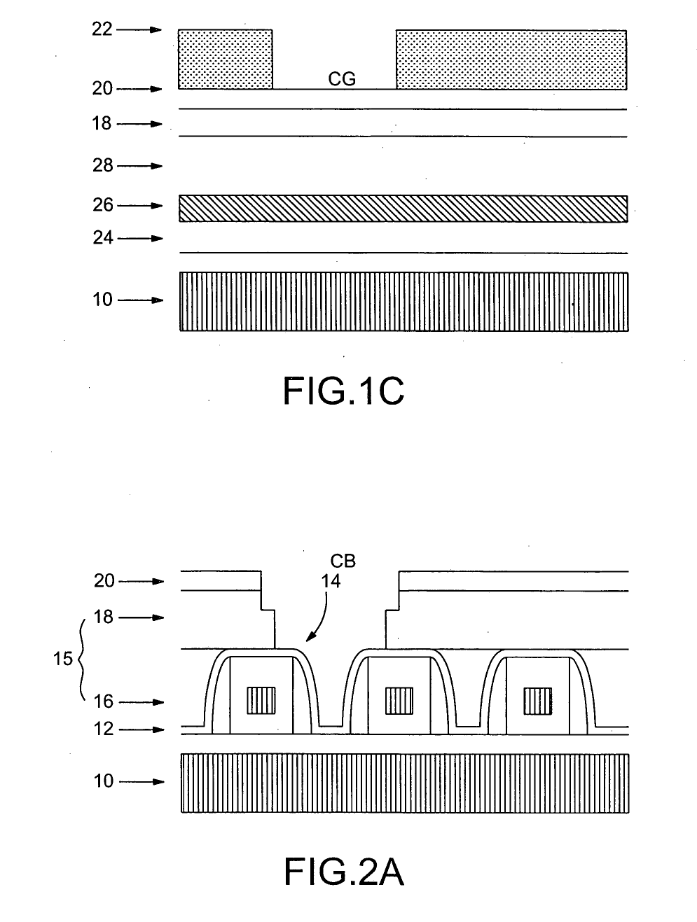

FIGS. 1A to 1C are cross-section views of a initial structure during the contact hole formation in accordance with the present invention;

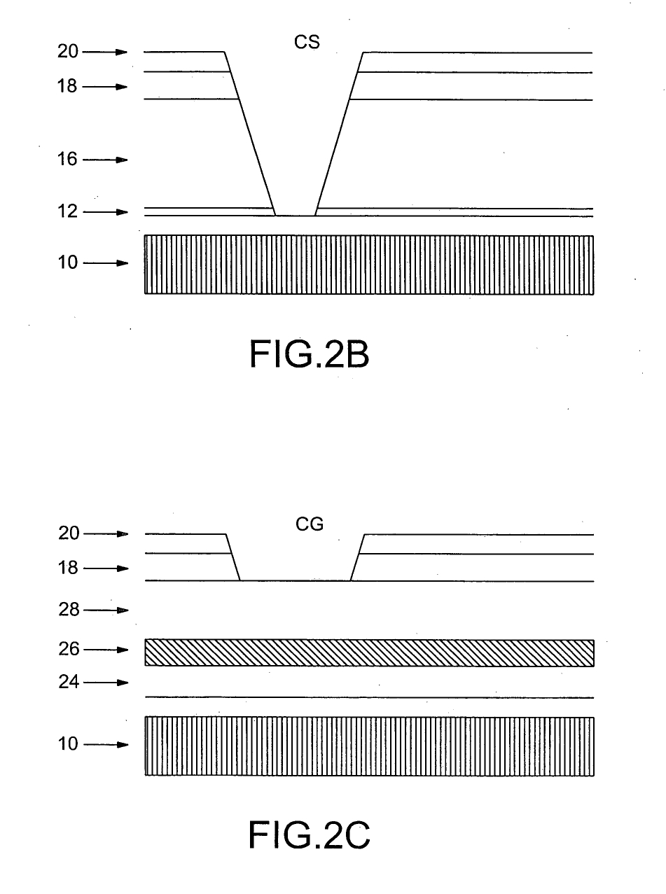

FIGS. 2A to 2C are cross-section views showing the present invention after etching the structure shown in FIGS. 1A to 1C;

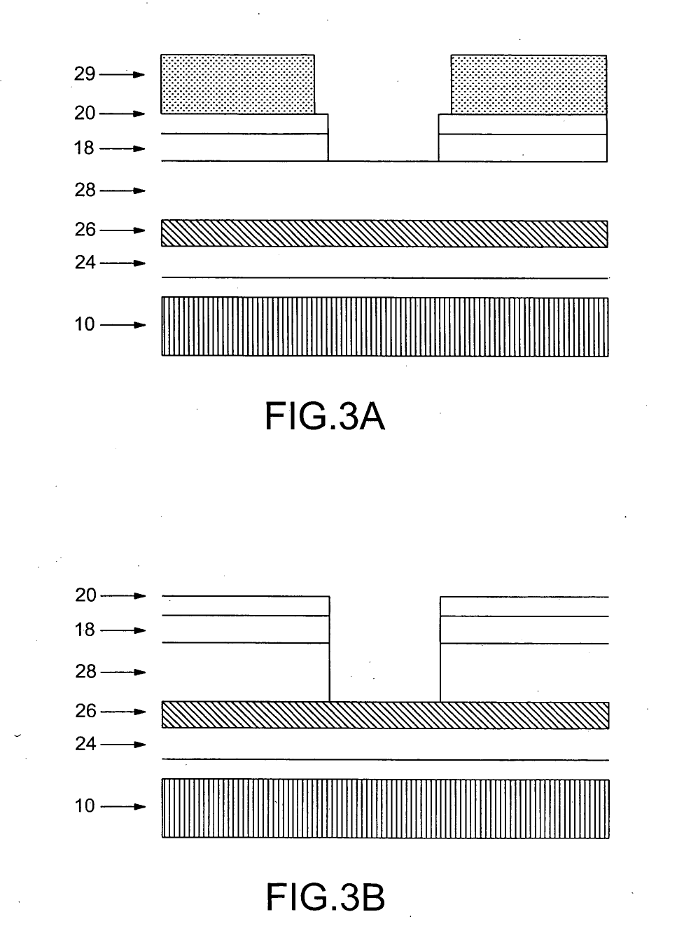

FIGS. 3A and 3B are cross-section views showing the present invention after etching the structure shown in FIG. 2C;

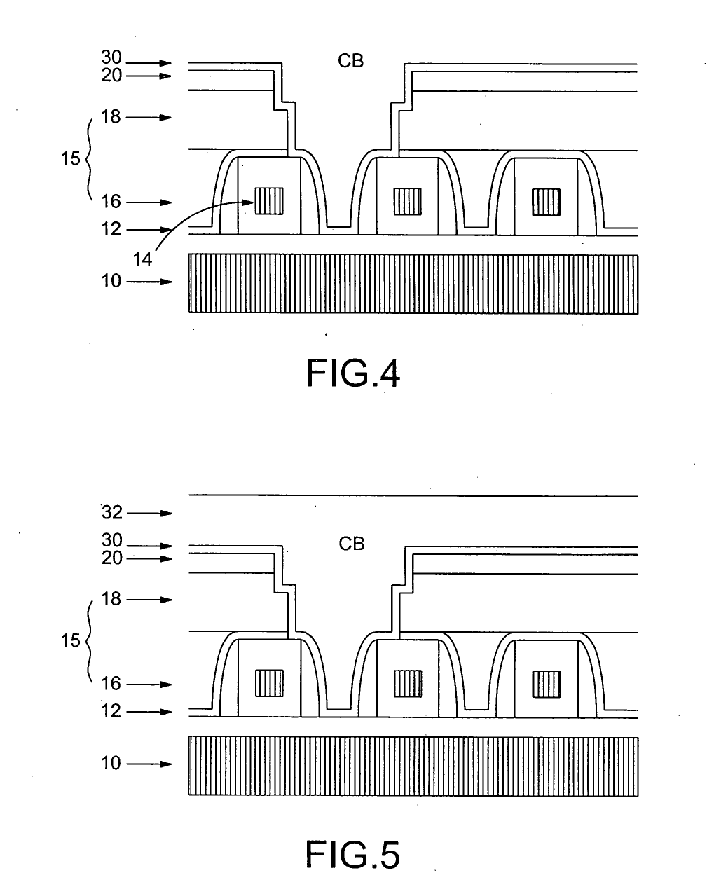

FIG. 4 to 6 are cross-section views showing the sequential steps of the method of forming the structure shown in FIG. 2A;

FIG. 7 illustrates a top view of the bit line and the word line structure; and

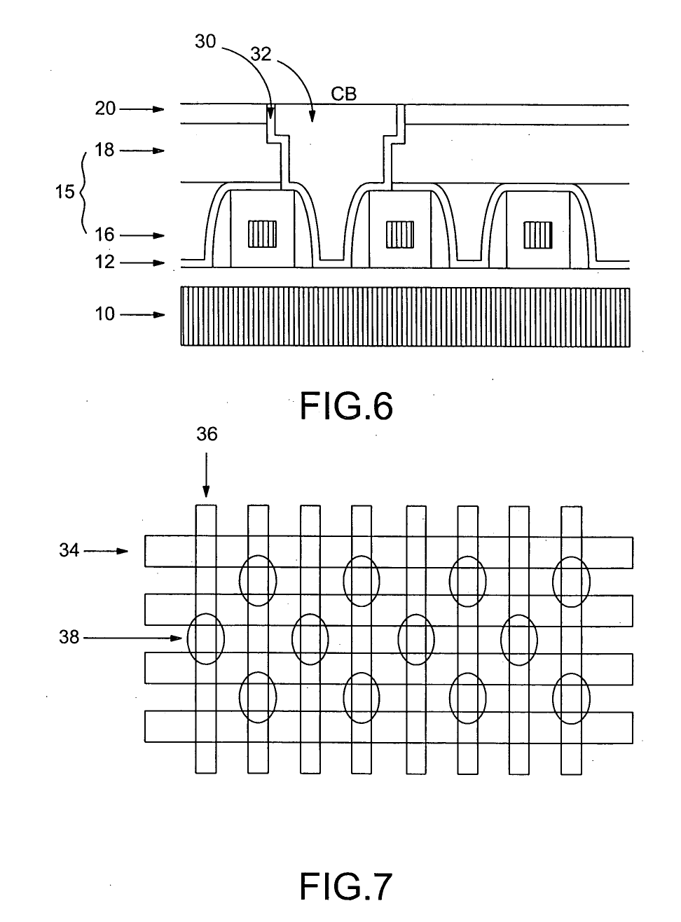

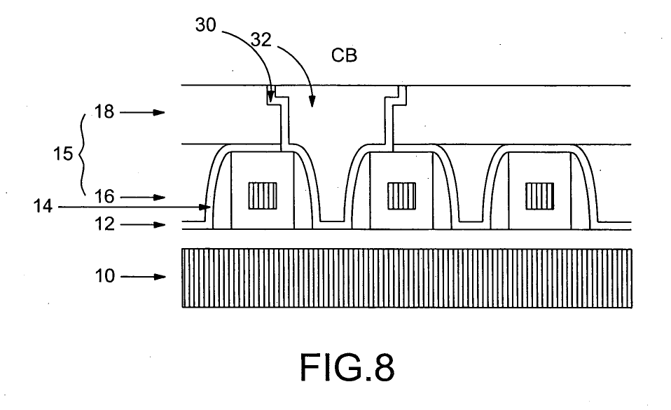

FIG. 8 illustrates a cross-section view showing the present invention after etching the structure shown in FIG. 6.

### DETAILED DESCRIPTION OF THE INVENTION

The present invention provides a method to make DRAM capable of avoiding bit line leakage. The embodiments of the present invention adopt 0.11-um process technology. However, the invention is not so limited. Other process technologies, such as 0.15 um and 0.18 um, can alternatively be adopted, with scaling up or down the process line width by a linear factor. By referring to the Figures and the following illustrations, which are illustrative purpose rather than restrictive, it is expected that the persons skilled in the art may fully understand and utilize the advantages of the present invention. It is noted that some illustrations, elements and/or layers shown in the diagrams may be simplified or even omitted because these are well known to persons skilled in the arts.

FIGS. 1A to 1C represent the cross-section views of preliminary structure of bit line contact hole, substrate contact hole and gate contact hole respectively.

With reference to FIG. 1A, a plurality of transistors 14 are formed on a substrate 10, and an insulating nitride layer 12, such as silicon nitride, is sequentially and conformally formed on the substrate 10. An insulating layer 15 with even surface is formed on the insulating nitride layer 12. The insulating layer 15 can be a multi-layer of BPSG layer 16 and TEOS layer 18, which are formed by depositing BPSG layer 16 with a thickness of about 2700-3300 nm, performing chemical mechanical polishing to planarize the BPSG layer 16 until a part of the insulating nitride layer 12 is exposed, and by depositing TEOS layer 18 with a thickness of about 2700-3300 nm. A photoresist layer can have a thickness of about 5000 Å in 0.2-um process technology, but only has an insufficient thickness of about 2600 Å in 0.11-um process technology. Therefore, a polysilicon layer 20 with a thickness of about 800-1200 Å, which is configured to be a hard mask, is formed over the insulating layer 15. Then, a desired location of a bit line contact hole is defined by a first photoresist 22.

With reference to FIG. 1B, an insulating nitride layer 12 is formed on a substrate 10, and an insulating layer 15, which can be a multi-layer of BPSG layer 16, and TEOS layer 18 is sequentially formed on the insulating nitride layer 12. A polysilicon layer 20 is formed over the insulating layer 15, and then a desired location of a substrate contact hole is defined by a first photoresist 22.

With reference to FIG. 1C, an conducting layer 24, such as a polysilicon, is formed on a substrate 10, and then a gate electrode 26, such as tungsten, is formed on the conducting layer 24. A cap nitride layer 28 and a TEOS layer 18 are sequentially formed over the gate electrode 26. Afterward a polysilicon layer 20 is formed over the TEOS layer 18, and then a desired location of a gate contact hole is defined by a first photoresist 22. Furthermore, the layers which are the common in FIGS. 1A to 1C are formed in the same photolithography process.

After forming gaps in the poly-silicon layer 20 of FIGS. 1A to 1C simultaneously by an etching process, the second etching process is performed by using the poly-silicon layer 20 as a hard mask, which consumes about 500 Å thickness of the poly-silicon layer 20. Then, the first photoresist 22 is removed, as shown in FIGS. 2A to 2C. The surface of the substrate 10 is exposed in the bit line contact hole and in the substrate contact hole. However, in the gate contact hole, the cap nitride layer 28 acts as an etching stop layer, and therefore the depth of the gate contact hole can only reach to the surface of the cap nitride layer 28 without exposing the surface of the gate electrode 26, as shown in FIG. 2C. For exposing the surface of the gate electrode 26, another etching process is performed in the gate contact hole. Referring to FIG. 3A, a desired location of a gate contact hole is defined by a second photoresist 29. The gate contact hole is etched again to expose the surface of the gate electrode 26, which consumes about 100 Å thickness of the poly-silicon layer 20, and then the second photoresist 29 is removed, as shown in FIG. 3B.

Referring to FIG. 4A, after the formation of the bit line contact hole, the substrate contact hole and the gate contact hole (as shown in FIGS. 2A, 2B and 2C), a barrier layer 30, which comprises a multilayer of a TiN layer and a Ti layer is conformally formed on the inner-surface of these contact holes and the poly-silicon layer 20. Since most leakage phenomena are observed at the bit line, the subsequent description will only show the process of the bit line contact. Although FIGS. 4 to 6 and FIG. 8 illustrate the bit line contact hole without showing the substrate contact hole and the gate contact hole, all of these contact holes are undergone the same process.

A layer of TiSi₂ will be generated between the Ti layer and any silicide material while heating the barrier layer 30. Next, a conducting layer 32, such as tungsten, is formed over the barrier layer 30 to fill the contact holes, as shown in FIG. 5. Referring to FIG. 6, a polishing method, such as chemical mechanical polishing, is performed to planarize the conducting layer 32 until the surface of the poly-silicon layer 20 is exposed, which consumes about 200 Å thickness of the poly-silicon layer 20. Thus it can be seen that remainder of the thickness of the poly-silicon layer 20 is about 200 Å.

Some scratches may be generated after employing the chemical mechanical polishing to planarize the conducting layer 32 because the TiSi₂ layer is difficult to polish. Referring to FIG. 7, a top view of the structure of the bit lines 36, word lines 34 and bit line contacts 38, the types of leakage vary with the locations of the scratches, such as bit line to bit line leakage, bit line contact to bit line contact leakage and bit line to bit line contact leakage. To solve this problem, the surface of the conducting layer 32 is microetched by O₂/O₃ plasma to remove the scratches caused by the chemical mechanical polishing or the stringers of the poly-silicon layer. The O₂/O₃ plasma, which is usually used to etch the photoresist, has characteristics of small etching rate of metal, and therefore the present invention uses the characteristics of the O₂/O₃ plasma to remove the scratches.

Except for using the O₂/O₃ plasma, another embodiment of the present invention uses an etchant of H₂SO₄, H₂O₂ and HF to microetch the conducting layer 32 in the room temperature. In the etchant, the volume ratio of H₂SO₄ to H₂O₂ is 20:1 to 12:1 and the concentration of HF is smaller than 8 ppm. The etching rate of metal is small due to the low concentration of HF and varies with the properties of various metals, which is about lower than 20 Å per minute for the embodiment of the present invention.

After completing the above steps, for eliminating the remainder leakage or just being a precaution against leakage, the poly-silicon layer can further be etched by a Cl-based or a Br-based plasma for eliminating the remainder leakage or for a precaution against leakage, as shown in FIG. 8.

Although the specific embodiments of the present invention have been illustrated and described, it is to be understood that the invention is not limited to those embodiments. One skilled in the art may make various modifications without departing from the scope or spirit of the invention.

1. A method of forming a DRAM capable of avoiding bit line leakage, comprising the steps of:
forming a transistor on a substrate, said transistor comprising a gate, a drain and a source;
forming an insulating layer to cover said substrate and said transistor;
forming a poly-silicon layer over said insulating layer;
forming a contact hole in said poly-silicon layer and said insulating layer, said contact hole touching said substrate;
filling said contact hole with a conducting layer; and
microetching a surface of said conducting layer.

2. The method of claim 1, wherein the step of microetching said surface of said conducting layer is with O₂/O₃ plasma.

3. The method of claim 1, wherein the step of microetching said surface of said conducting layer is with an etchant comprised of H₂SO₄, H₂O₂ and HF.

4. The method of claim 3, wherein the volume ratio of H₂SO₄ to H₂O₂ in said etchant is 20:1 to 12:1, and the concentration of HF is smaller than 8 ppm.

5. The method of claim 1, wherein said insulating layer comprises a first insulating layer and a second insulating layer, and the step of forming said insulating layer comprises the steps of:
forming said first insulating layer to cover said substrate and said transistor;
planarizing said first insulating layer to expose an upper surface of said gate of said transistor; and
forming said second insulating layer to cover said insulating layer and said upper surface of said gate.

6. The method of claim 1, wherein said first insulating layer is BPSG (boron-phosphosilicate glass) and said second insulating layer is tetraethoxysilane (TEOS).

7. The method of claim 1, further comprising the steps of:
conformally forming a barrier layer on said poly-silicon layer and an inner-surface of said contact hole prior to forming said conducting layer, said barrier layer comprising a multi-layer of a titanium nitride layer and a titanium layer.

8. The method of claim 1, wherein said conducting layer is tungsten.

9. The method of claim 1, further comprising the steps of:
after forming said conducting layer, polishing said conducting layer until an upper surface of said poly-silicon is exposed.

10. The method of claim 1, further comprising the steps of:
after microetching the surface of said conducting layer, etching said polysilicon layer with Cl-based or Br-based plasma.

11. A method of forming a DRAM capable of avoiding bit line leakage, comprising the steps of:
forming a transistor on a substrate, said transistor comprising a gate, a drain and a source;
forming a first insulating layer to cover said substrate and said transistor;
planarizing said first insulating layer to expose an upper surface of said gate of said transistor;
forming a second insulating layer to cover said insulating layer and said upper surface of said gate;
forming a poly-silicon layer over said second insulating layer;
forming a contact hole in said poly-silicon layer, said first insulating layer and said second insulating layer, said contact hole touching said substrate;
conformally forming a barrier layer on said poly-silicon layer and an inner-surface of said contact hole, said barrier layer comprising a multi-layer of a titanium nitride layer and a titanium layer;
filling said contact hole with a conducting layer;
polishing said conducting layer until an upper surface of said poly-silicon is exposed; and
microetching a surface of said conducting layer with O₂/O₃ plasma.

12. The method of claim 11, wherein said first insulating layer is BPSG (boron-phosphosilicate glass) and said second insulating layer is tetraethoxysilane (TEOS).

13. The method of claim 11, wherein said conducting layer is tungsten.

14. The method of claim 11, further comprising the steps of:
after microetching the surface of said conducting layer, etching said poly-silicon layer with Cl-based or Br-based plasma.

15. A method of forming a DRAM capable of avoiding bit line leakage, comprising the steps of:
forming a transistor on a substrate, said transistor comprising a gate, a drain and a source;
forming a first insulating layer to cover said substrate and said transistor;
planarizing said first insulating layer to expose an upper surface of said gate of said transistor;
forming a second insulating layer to cover said insulating layer and said upper surface of said gate;
forming a poly-silicon layer over said second insulating layer;
forming a contact hole in said poly-silicon layer, said first insulating layer and said second insulating layer, said contact hole touching said substrate;
conformally forming a barrier layer on said poly-silicon layer and an inner-surface of said contact hole, said barrier layer comprising a multi-layer of a titanium nitride layer and a titanium layer;
filling said contact hole with a conducting layer;
polishing the material of said conducting layer until an upper surface of said poly-silicon is exposed; and
microetching a surface of said conducting layer with an etchant comprised of H₂SO₄, H₂O₂ and HF, wherein the volume ratio of H₂SO₄ to H₂O₂ in said etchant is 20:1 to 12:1, and the concentration of HF is smaller than 8 ppm.

16. The method of claim 15, wherein said first insulating layer is BPSG (boron-phosphosilicate glass) and said second insulating layer is tetraethoxysilane (TEOS).

17. The method of claim 15, wherein said conducting layer is tungsten.

18. The method of claim 15, further comprising the steps of:
after microetching the surface of said conducting layer, etching said poly-silicon layer with Cl-based or Br-based plasma.
